(19) United States
(12) Patent Application Publication
(10) Pub. No.: US 2006/0097298 A1
(43) Pub. Date: May 11, 2006

(54) Magnetic random access memory with reduced currents in a bit line and manufacturing method thereof

(75) Inventor: Ching-Yuan Ho, Hsinchu (TW)

Correspondence Address: HDSL, 4331 STEVENS BATTLE LANE, FAIRFAX, VA, 22033, US

(73) Assignee: Industrial Technology Research Institute

(21) Appl. No.: 11/119,880

(22) Filed: May 3, 2005

(30) Foreign Application Priority Data
Nov. 9, 2004 (TW) 93134144

(51) Int. Cl. H01L 29/94

(52) U.S. Cl. 257/295

(57) ABSTRACT

A magnetic random access memory with reduced currents in a bit line and a manufacturing method thereof. In one embodiment, the memory includes a bottom electrode, a first dielectric layer on the bottom electrode, a via in the first dielectric layer, a magnetic tunnel junction (MTJ) element that is aligned with and formed on a via, and a metal layer that is formed on and in contact with an MTJ element. In another embodiment, a second dielectric layer is formed on the first dielectric layer, and a metal layer is formed on and in contact with an MTJ element and the second dielectric layer. These designs can protect the MTJ element from damage during the etching process. Hence it increases the stability and the yield rate during the manufacturing process. Furthermore, the designs can reduce the current requirements of running magnetic cells, thereby reducing power consumption.

This application claims the benefit of Taiwan Patent Application No. 93134144, filed on Nov. 9, 2004, which is hereby incorporated by reference for all purposes as if fully set forth herein.

### BACKGROUND OF THE INVENTION

1. Field of Invention

The invention relates to a magnetic random access memory and its manufacturing method and, in particular, to a method for making a magnetic random access memory with reduced currents in a bit line.

2. Related Art

A magnetic random access memory (MRAM) is a non-volatile memory, which uses the characteristics of resistance to record data. Its features are non-volatility, high density, high read-write speed and anti-radiation. For a write operation, the commonly used method for selecting a memory cell is to find the intersection location of two magnetic fields produced respectively by a bit line and a write word line. It changes the value of its resistance by changing the polarization direction of the magnetic material of the memory layer at the memory cell. For a read operation, a current is sent to the selected magnetic memory cell to read the value of the memory layer resistance. The value of the stored data is determined by the value of its resistance received.

Currently, the structure of magnetic random access memory between a bit line and a write line comprises multiple layers of magnetic metal stacked together. It includes a soft magnetic layer, a tunnel barrier layer, a hard magnetic layer and a nonmagnetic conductor layer. The state of “1” or “0” is determined by parallel or non-parallel polarization of two layers of magnetic material.

During a read operation, the word line triggers the reading transistor so its current can pass through the Magnetic Tunnel Junction (MTJ) of MRAM to the drain electrode. MTJ obtains a 0 or 1 value by receiving respectively a low or a high voltage produced by a positive or a negative magnetic polarization vector of the pin layer and the free layer.

FIG. 1 illustrates the structure of an MRAM in the prior art, where a magnetic memory cell is formed between two metal vias. The process forms a metal electrode 101 and a via 102 in a substrate 100. It then deposits a dielectric layer 104 and uses a mask pattern and etching to form two vias 105 and 106. The via 105 provides a current path and the contact hole 106 is a write word line to provide a magnetic field during the write operation. The cap layers 103 and 107 work as stop layers during the etching process. It then forms a bottom electrode 108 on the cap layer 107 and a magnetic memory cell 109 that is covered by a dielectric layer 110. Lastly, it forms a via 111 and a bit line 112.

In the prior art, the structure of the MRAM is difficult to control during the yellow-light etching process. This causes failure of devices. A magnetic memory cell 109 can be damaged during etching when a conductive layer and a via 111 are not aligned precisely with a magnetic memory cell 109. This is because the size of the connecting region between the bottom electrode 108 and the magnetic memory cell 109 is less than 0.05 um. And the size of connecting region between the via 111 and the magnetic memory cell 109 is also less than 0.05 um. Therefore, if the yellow-light is misaligned, a magnetic memory cell 109 could be etched and damaged.

Another technical difficulty is that etching the via is hard to control since a magnetic memory cell 109 uses Ta or SiN as a hard mask that serves as a stop layer while etching the via. However, the oxide CMP of the via may cause uneven thickness, in which the thinner part of the via may be overly etched and the hard mask may not effectively prevent MTJ from being penetrated. An uneven thickness of the inter-metal dielectric layer (IMD) may prevent the via from not opening.

To increase memory density, the MTJ has very small margin to align with other parts in the following processes, which greatly increases difficulty in manufacturing. This is the most important factor in making quality MRAM. It has thus become necessary to develop a new kind of MRAM that requires less current in running magnetic fields on free-layers. The new MRAM must be easy to manufacture and its yield rate increased.

### SUMMARY OF THE INVENTION

The invention provides an MRAM with reduced currents in a bit line, which solves the existing problems in the previous technology. The invention also provides its manufacture method.

One embodiment of the invention comprises a bottom electrode, a first dielectric layer formed on the bottom electrode, a via formed in the first dielectric layer, an MTJ aligned with and formed on the via, and a metal layer directly formed on the MTJ.

Another embodiment of the invention comprises a bottom electrode, a first dielectric layer formed on the bottom electrode, a via formed in the first dielectric layer, an MTJ aligned with and formed on the via, a second dielectric layer formed on the first dielectric layer, and a metal layer directly formed on the MTJ and the second dielectric layer

One manufacturing embodiment of the invention comprises the following steps: forming a bottom electrode, forming a first dielectric layer on the bottom electrode, forming a via in the first dielectric layer, forming an MTJ on the via, depositing a cap layer on the MTJ and the first dielectric layer, depositing a second dielectric layer on the cap layer, etching the cap layer and the second dielectric layer, and depositing a metal layer in contact with the MTJ.

Another manufacturing embodiment of the invention comprises: forming a bottom electrode, forming a first dielectric layer on the bottom electrode, forming a via in the first dielectric layer, forming an MTJ on the via, depositing a cap layer on the MTJ and the first dielectric layer, depositing a second dielectric layer on the cap layer, and depositing a metal layer in contact with the MTJ and the second dielectric layer.

The invention of MRAM with reduced currents in a bit line can prevent damage of the MTJ caused by the following etching process and can increase manufacturing stability and yield rate.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a magnetic random access memory of the prior art;

FIG. 2 is a preferred embodiment of the invention;

FIG. 3A˜3F is a preferred manufacturing embodiment of the invention; and

FIG. 4 is another preferred manufacturing embodiment of the invention.

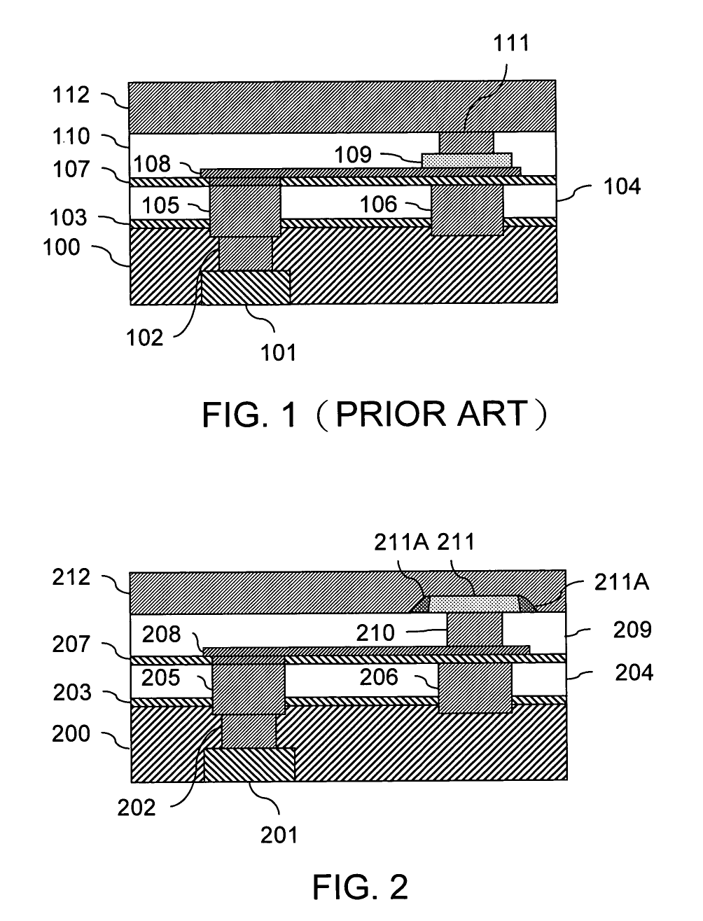

### DETAILED DESCRIPTION OF THE INVENTION

Reference will now be made in greater detail to a preferred embodiment of the invention, an example of which is illustrated in the accompanying drawings. Wherever possible, the same reference numerals will be used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

FIG. 2 illustrates one embodiment of the invention in which only a single magnetic random access memory (or memory cell) is shown. The actual memory array can be formed by a group of memory cells as shown in FIG. 2.

The memory cell comprises a substrate 200, in which a metal electrode 201 and a via hole 202 are formed. Then an interlayer dielectric layer 204 is deposited, in which two via holes 205 and 206 are formed by mask patterning and etching. The via hole 205 is for a current path and the via hole 206 is for a write word line to provide a magnetic field needed during data writing. The insulation layers 203 and 207 are used as stop layers during the etching process and can be made of SiN, for example.

A bottom electrode 208 is formed on the top surface of an insulation layer 207 and is in contact with the via hole 205. The first interlayer dielectric layer 209 is formed on the bottom electrode 208 and is aligned with the via hole 206. A via hole 210 is formed on the bottom electrode 208. A magnetic cell 211 is formed on the via hole 210, with a surrounding wall 211A to protect the magnetic cell 211. A metal layer 212 is formed directly on top surface of the magnetic cell 211. The via holes 205, 206 and 210 are filled with metal material.

The magnetic cell 211, for example, can have multiple layers—from bottom to top they are the buffer layer, anti-ferromagnetic layer, pin layer, tunnel barrier layer and free layer. The buffer layer can be made of NiFe or NiFeCr. The anti-ferromagnetic layer can be made of PtMn or MnIr. The pin layer can be made of more than one layer of ferromagnetic material or the three-layer structure of man-made anti-ferromagnetic material, e.g., CoFe/Ru/CoFe or CoFe/Ru/CoFe. The tunnel barrier layer can be made of AlOx. The free layer can be made of more than one layer of ferromagnetic material or the three-layer structure of man-made anti-ferromagnetic material. The magnetic layer can be made of NiFe/CoFe or CoFeB. The man-made anti-ferromagnetic free layer can be made of CoFe/Ru/CoFe or CoFeB/Ru/CoFeB. The above-mentioned material and structure are only for explanation purposes, and other magnetic materials can be chosen to achieve the same results.

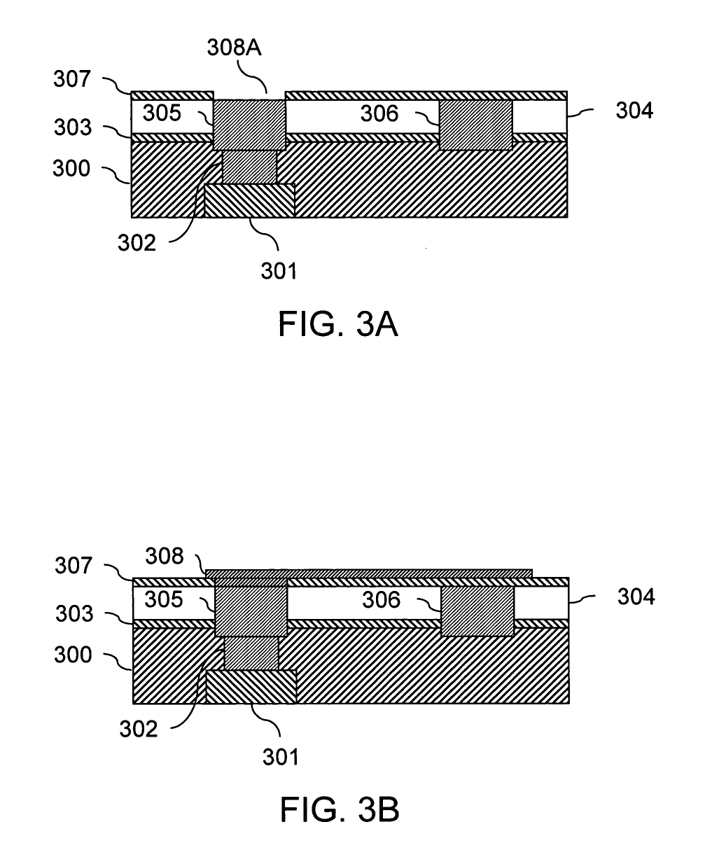

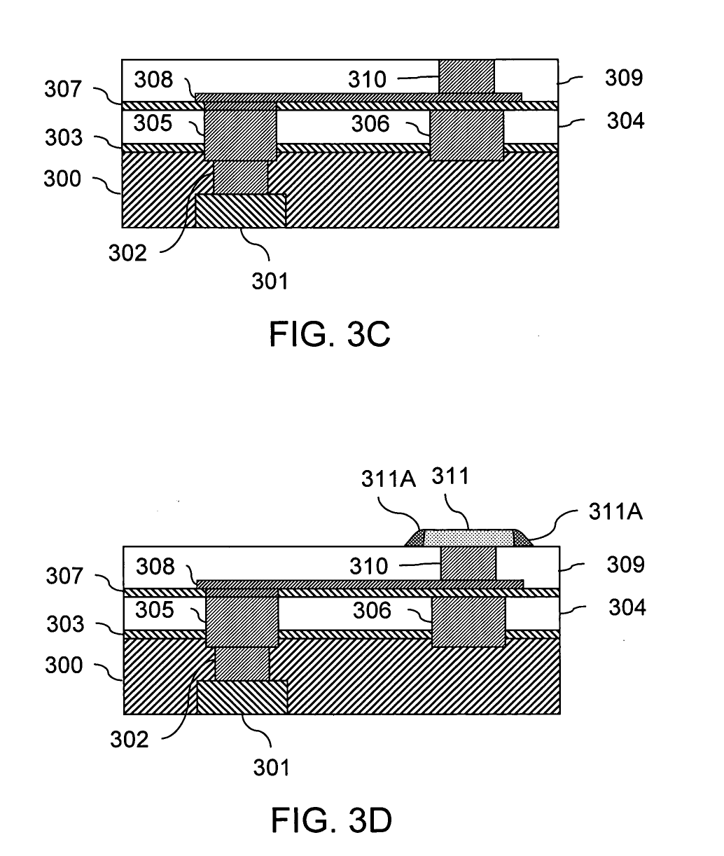

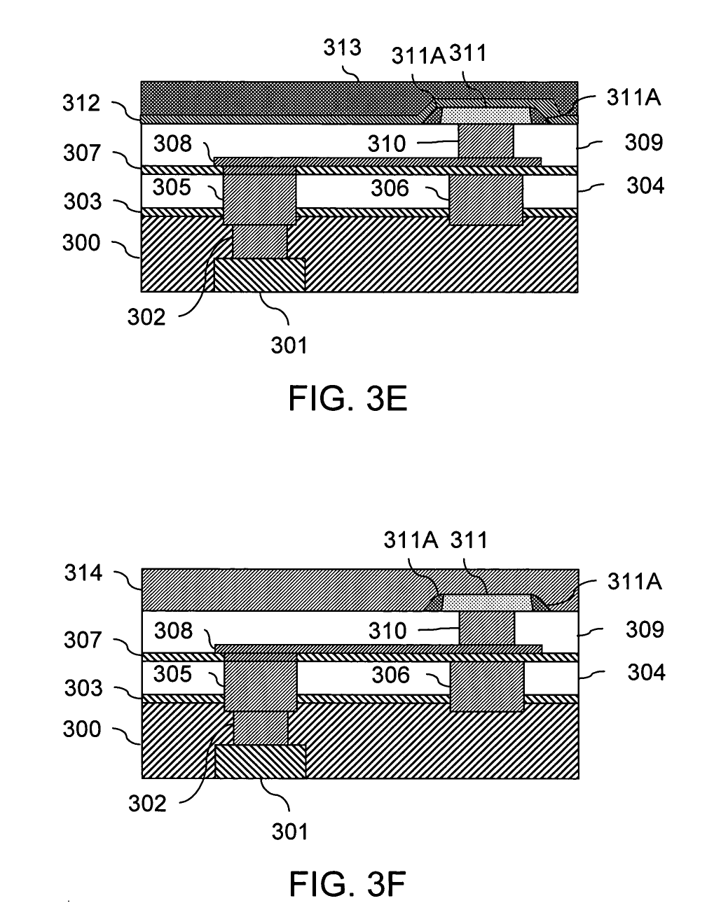

FIG. 3A˜3F illustrate one manufacturing embodiment of the invention. The steps and order are not fixed or may be omitted; some steps can be implemented simultaneously, omitted or added. The flow chart is a common, easy way to describe the invention, and is not intended to limit the manufacturing steps or orders.

Referring to FIG. 3A, the first part of the manufacturing process includes a substrate 300, in which a metal electrode 301 and a via hole 302 are formed. It then deposits an interlayer dielectric layer 304, in which two via holes 305 and 306 are formed by optical masking and etching. It fills the via holes 305 and 306 with metal material. The insulation layers 303 and 307 are used as etching stop layers. For example, the insulation layers 303 and 307 can be made of SiN. It then defines the bottom electrode contact hole 308A on the insulation layer 307 using optical masking and aligns the bottom electrode contact hole with the via hole 305.

Then, the bottom electrode 308 is deposited and formed as shown in FIG. 3B.

Next, the first interlayer dielectric layer 309 is deposited and formed, in which the pattern of the via hole 310 is defined by an optical mask. The via hole 310 is formed through etching and is then filled with metal as shown in FIG. 3C. The via hole 310 is in contact with the bottom electrode 308. Thus, it forms a current path through the via hole 302, via hole 305, bottom electrode 308 and via hole 310.

Next, the process proceeds to deposit a magnetic cell 311 as shown in FIG. 3D. It uses the conductive material Ta as hard mask during etching. It also deposits SiN on a magnetic cell 311 to form a surrounding wall 311A by etching. The surrounding wall 311A is used to protect the magnetic cell 311 from damage during the following etching for making a bit line.

It then forms an insulation layer 312 by depositing SiN on the first interlayer dielectric layer 309 and a magnetic cell 311. It also forms the second dielectric layer 313 on an insulation layer 312, as shown in FIG. 3E.

Lastly, the process performs trench etching on an insulation layer 312 and the second interlayer dielectric layer 311. It then deposits a metal layer 314 on the first dielectric layer 309 and a magnetic cell 311, as shown in FIG. 3F. The metal layer can be made of copper, for example.

In this embodiment, a magnetic cell is buried in a bit line and is in direct contact with the bit line. This approach can reduce the distance between the magnetic cell and the bit line to reduce the current required in the bit line.

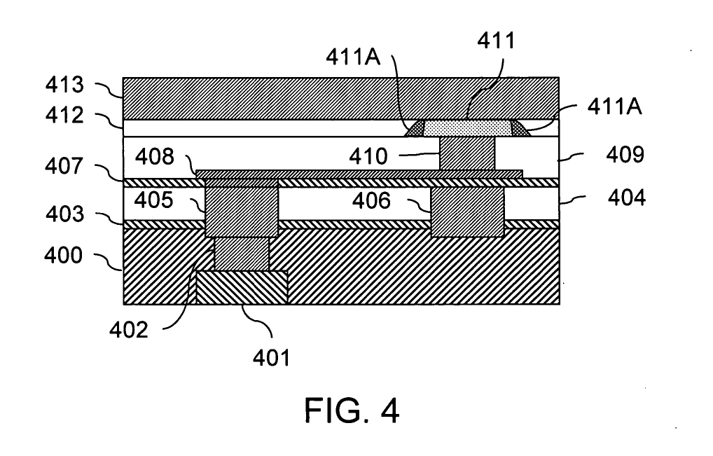

FIG. 4 illustrates another embodiment of the invention. The embodiment includes a substrate 400, a metal electrode 401, a via hole 402, an insulation layer 403, an interlayer dielectric layer 404, a via hole 405, a via hole 406, an insulation layer 407, a bottom electrode 408, a first interlayer dielectric layer 409, a via hole 410, a magnetic cell 411 and a surrounding wall 411A. All these components are similar to the above-mentioned embodiment in terms of functionality, structure and manufacturing method. Thus, their descriptions are omitted here.

The difference of this embodiment is that the second interlayer dielectric layer 412 is deposited on a magnetic memory cell 411, and a metal layer 413 is then formed on the dielectric layer 412 as a bit line.

In this embodiment, a via hole 410 is below a magnetic cell 411. The metal layer 413 as bit line can be produced by dual damascene, for example.

In the invention, a magnetic cell is formed inside a metal layer or in contact with the metal layer. The difference from the previous technology is that the invention moves the process of making a bottom electrode and a via hole to before the magnetic cell is made, since the magnetic cell can be easily damaged by the bottom electrode. Furthermore, it forms a surrounding wall to protect the magnetic cell after it is formed. It defines a bit line that is in direct contact with the magnetic cell. The surrounding wall is made of SiN and is used as an etching stop layer during trench etching of the bit line.

The optical mask layout for the MRAM of the invention is the same as the traditional structure. The difference is that it moves the layout of the bottom electrode conductive line and the via to before the magnetic cell is made.

The invention of MRAM improves the traditional structure and resolves the manufacturing bottleneck. By making the bit line directly in contact with the magnetic cell, the invention can reduce the current requirements and the power consumption.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A magnetic random access memory with reduced currents in a bit line, comprising:
a bottom electrode;
a first dielectric layer formed on the bottom electrode;
a via formed in the first dielectric layer;
a magnetic tunnel junction (MTJ) aligned to be formed on the via; and
a metal layer contact formed on the MTJ.

2. The magnetic random access memory of claim 1, wherein the bottom electrode is formed above a substrate having a metal electrode and a via.

3. The magnetic random access memory of claim 2, further comprising a second dielectric layer having at least one via, formed on the substrate.

4. The magnetic random access memory of claim 3, further comprising a cap layer formed between the substrate and the second dielectric layer.

5. The magnetic random access memory of claim 3, further comprising a cap layer formed between the first dielectric layer and the second dielectric layer.

6. The magnetic random access memory of claim 1, further comprising a side wall formed around the MTJ.

7. A magnetic random access memory with reduced currents in a bit line, comprising:
a bottom electrode;
a first dielectric layer formed on the bottom electrode;
a via formed in the first dielectric layer;
a magnetic tunnel junction (MTJ) aligned to be formed on the via;
a second dielectric layer formed on the first dielectric layer; and
a metal layer contact formed on the MTJ and the second dielectric layer.

8. The magnetic random access memory of claim 7, wherein the bottom electrode is formed above a substrate having a metal electrode and a via.

9. The magnetic random access memory of claim 7, further comprising a third dielectric layer having at least one via formed on the substrate.

10. The magnetic random access memory of claim 9, further comprising a cap layer formed between the substrate and the third dielectric layer.

11. The magnetic random access memory of claim 9, further comprising a cap layer formed between the first dielectric layer and the third dielectric layer.

12. The magnetic random access memory of claim 7, further comprising a side wall formed around the MTJ.

13. A manufacture method of a magnetic random access memory with reduced currents in a bit line, comprising:
forming a bottom electrode;
forming a first dielectric layer on the bottom electrode;
forming a via in the first dielectric layer;
forming a magnetic tunnel junction (MTJ) on the via;
depositing a cap layer on the MTJ and the first dielectric layer;
depositing a second dielectric layer on the cap layer;
etching the cap layer and the second dielectric layer; and
depositing a metal layer in contact with the MTJ.

14. The manufacture method of a magnetic random access memory of claim 13, further comprising providing a substrate including a metal electrode and a via in the substrate before the step of forming a bottom electrode.

15. The manufacture method of a magnetic random access memory of claim 14, further comprising providing a substrate before the bottom electrode is formed, and forming a second dielectric layer on the substrate and forming at least one via in the second dielectric layer.

16. The manufacture method of a magnetic random access memory of claim 15, further comprising forming a cap layer between the substrate and the second dielectric layer.

17. The manufacture method of a magnetic random access memory of claim 15, further comprising forming a cap layer between the first dielectric layer and the second dielectric layer.

18. The manufacture method of a magnetic random access memory of claim 13, further comprising forming a side wall around the MTJ.

19. A manufacture method of a magnetic random access memory with reduced currents in a bit line, comprising:
forming a bottom electrode;
forming a first dielectric layer on the bottom electrode;
forming a via in the first dielectric layer;
forming a magnetic tunnel junction (MTJ) on the via;
forming a second dielectric layer on the first dielectric layer; and
depositing a metal layer in contact with the MTJ and the second dielectric layer;

20. The manufacture method of a magnetic random access memory of claim 19, further comprising providing a substrate including a metal electrode and another via in the substrate before the step of forming a bottom electrode.

21. The manufacture method of a magnetic random access memory of claim 20, further providing a substrate before the bottom electrode is formed, and forming a second dielectric layer on the substrate and forming at least one via in the second dielectric layer.

22. The manufacture method of a magnetic random access memory of claim 21, further comprising forming a cap layer between the substrate and the third dielectric layer.

23. The manufacture method of a magnetic random access memory of claim 21, further comprising forming a cap layer between the first dielectric layer and the third dielectric layer.

24. The manufacture method of a magnetic random access memory of claim 19, further comprising forming a side wall around the MTJ
